(19) United States
(12) Patent Application Publication
(10) Pub. No.: US 2025/0313481 A1
(43) Pub. Date: Oct. 9, 2025

(54) PROCESS FOR MANUFACTURING COBALT SILICIDE CoSi2

(71) Applicant: COMMISSARIAT A L'ENERGIE ATOMIQUE ET AUX ENERGIES ALTERNATIVES, PARIS (FR)

(72) Inventors: Paul DUMAS, GRENOBLE CEDEX 09 (FR); Mathieu OPPRECHT, GRENOBLE CEDEX 09 (FR); Fabrice NEMOUCHI, GRENOBLE CEDEX 09 (FR); François LEFLOCH, GRENOBLE CEDEX 09 (FR); Frédéric GUSTAVO, GRENOBLE CEDEX 09 (FR); Sébastien KERDILES, GRENOBLE CEDEX 09 (FR)

(21) Appl. No.: 19/172,118

(22) Filed: Apr. 7, 2025

(30) Foreign Application Priority Data
Apr. 8, 2024 (FR) FR2403618

(51) Int. Cl. C01B 33/06; C30B 23/02; C30B 29/10

(52) U.S. Cl. CPC C01B 33/06; C30B 23/025; C30B 29/10

(57) ABSTRACT

The invention relates to a method for manufacturing a cobalt silicide CoSi₂ layer including the steps of:
Providing a substrate comprising a silicon layer;
Depositing a cobalt Co layer onto the substrate;
Annealing the stack by a nanosecond laser comprising at least one laser pulse with a duration between 50 nanoseconds and 20 microseconds and an energy density selected so as to form the cobalt silicide CoSi₂ layer in the solid state.

### TECHNICAL FIELD

This invention generally relates to the field of materials used in microelectronics. It relates more particularly to cobalt silicide CoSi₂.

In particular, the present invention relates to a method for manufacturing a CoSi₂ layer. The invention also relates to an electronic device in which at least one zone, for example a contact, is made of CoSi₂ obtained by the method of the invention. The invention relates to, for example, but not limited to, a transistor in which the drain and source and/or gate contacts are made of CoSi₂. The invention may also relate to a JoFET (Josephson Field Effect Transistor) in which CoSi₂ is used as superconducting material for the drain and/or source.

### STATE OF THE ART

The physical properties of cobalt silicide CoSi₂ (good thermal stability, chemically inert, low resistivity) make it particularly suitable for forming contacts in CMOS technology manufacturing. This is especially true for making CoSi₂ contacts for the gate and/or source and drain of a CMOS transistor.

CoSi₂ is additionally a superconducting material and can therefore be used as a superconducting contact in a JoFET (Josephson Field Effect Transistor).

Forming CoSi₂ begins with depositing a thin layer of cobalt (Co) onto a silicon substrate, followed by two rapid thermal annealing (RTA) treatments lasting around ten seconds. Two RTAs are necessary because CoSi₂ is not the first silicide formed as a result of the reaction of Co with Si. Co deposition is performed, for example, by Physical Vapour Deposition (PVD). Each of the RTAs is made, for example, by conduction using heating blocks in proximity to the silicon wafer.

Once the cobalt has been deposited, the stack is subjected to an initial step of rapid heat treatment (RTA) at a temperature close to 500° C. During this first RTA treatment, cobalt reacts with silicon to form an intermediate CoSi layer, which forms a resistive phase. The purpose of this first step is to incorporate the necessary amount of Co in a controlled manner to avoid the semiconductor being completely consumed, for example in the source and drain zones. Unreacted Co is then selectively removed, for example by means of a selective etching step. This step avoids forming undesired zones of cobalt metal on the substrate.

Once the excess cobalt has been removed, the stack is subjected to a second RTA step at a higher temperature, typically between 60° and 900° C. This step makes it possible to transform CoSi into CoSi₂.

In addition to the complexity and cost of the process, however, the formation of CoSi₂ described above poses some difficulties. Indeed, the relatively high temperature of the second RTA indicates that it is difficult for CoSi₂ to nucleate from CoSi, as the two silicides have very similar formation energies. This results in forming a CoSi₂/Si interface that is not sufficiently planar and is therefore likely to arise some problems in achieving an effective Josephson effect. Furthermore, when the dimensions of the contact to be made become too small (for example with a critical dimension CD strictly lower than 100 nm), the surface energy becomes too low relative to the volume energy and some zones remain of CoSi.

Another solution for the formation of CoSi₂ consists in performing, after depositing Co on Si, a first RTA treatment to form CoSi and then a second treatment by nanosecond laser annealing (pulse in the order of 30 ns) to form CoSi₂ in the liquid state. Once again, this solution has some drawbacks. A CoSi/CoSi₂ transition is once again observed, with the same difficulties for CoSi₂ to nucleate from CoSi. Furthermore, the liquid transition of CoSi₂ leads to significant stresses for wafers including a plurality of patterns (patterned wafers), with elements that can melt before Co (sensitivity of a transistor gate, for example). Finally, additional oven annealing may also be necessary to remove interface defects, making the process long and costly.

### SUMMARY OF THE INVENTION

The aim of the present invention is therefore to improve known methods for manufacturing cobalt silicide CoSi₂, especially by avoiding the nucleation problems associated with the CoSi/CoSi₂ transition, by advantageously using a single step for making the material, unlike two-step methods, especially RTA, ensuring better flatness of the Si/CoSi₂ interface and dispensing with CoSi₂ turning to the liquid state, said method being additionally compatible with three-dimensional integrations in which several levels of transistors are built on a same wafer.

To that end, the invention relates to a method for manufacturing a cobalt silicide CoSi₂ layer including the steps of:
Supplying of a substrate comprising a silicon layer
Depositing a cobalt Co layer onto the substrate;
Annealing the stack by a nanosecond laser comprising at least one laser pulse with a duration between 50 nanoseconds and 20 microseconds and an energy density selected so as to form the cobalt silicide CoSi₂ layer in the solid state.

Particularly surprisingly, it has been noticed that the formation of CoSi₂ could advantageously be carried out in the solid state by pulsed laser annealing using at least one pulse of a duration between 50 ns and 20 microseconds. By solid state, it is meant that the melting temperature of Co, Si or any Co silicide, in the order of at least 1350° C., is never reached during laser annealing. As will be seen later, it is possible to make one or more pulses of the same or different energy density. The protective layer protects the cobalt and/or silicon layers from oxidation. It is understood that the material of the protective layer, for example TiN, has to be selected to allow sufficient passage or absorption of the laser radiation so that the latter reaches the surface of the cobalt layer. The method of the invention enables CoSi₂ to be manufactured without going through a CoSi/CoSi₂ transition. By virtue of the invention, it is possible to dispense with two RTA steps. Additionally, the invention makes it possible to obtain improved flatness at the CoSi₂/Si interface. The fact that the CoSi₂ remains in the solid state also makes it possible to further limit integration problems associated with the melting of other zones in a component, for example the gate of a transistor. The method of the invention also makes it possible to obtain a CoSi₂ material with a sheet resistance Rs (Rsheet) comparable to the sheet resistance of CoSi₂ obtained by techniques of the state of the art and with a critical superconductivity temperature Tc that is also comparable, or even higher in some situations. Sheet resistance can be seen as the ratio of the resistivity of the material to its thickness.

It will be noted that Co deposited may be slightly alloyed with a metal M, for example platinum Pt, which is only slightly present; in this case, cobalt silicide including a small percentage by mass of metal M will be obtained, without departing from the scope of the invention.

It will also be noted that the Co layer can be deposited directly onto the Si layer but there could also be an oxide or nitride layer between the Si layer and the Co layer (in the latter case, the oxide or nitride layer is preferably no more than 2 mm thick so that CoSi₂ can form).

Further to the characteristics just discussed in the preceding paragraphs, the manufacturing method according to the invention may have one or more additional characteristics from among the following, considered individually or according to any technically possible combination:
The method includes a step in which a layer protecting Co and/or Si from oxidation, such as a TiN layer, is deposited onto the Co layer before the annealing step.
The duration of the laser pulse is between 0.1 microsecond and 1 microsecond.
Laser annealing is performed in the form of a single laser pulse.
Laser annealing is performed in the form of a plurality of laser pulses.
The trigger frequency of the laser pulses is between 0.1 Hz and 1000 Hz, advantageously between 1 Hz and 10 Hz and even more advantageously between 3 Hz and 6 Hz.
Each laser pulse of said plurality of laser pulses is emitted with the same energy density.
The first laser pulse of said plurality of laser pulses has a higher energy density than the subsequent pulses, the energy density of the first pulse being selected close to but strictly lower than the energy density causing melting of the cobalt silicide CoSi₂.
The thickness of the Co layer is between 0.5 and 50 nm and preferably between 1 and 10 nm.
The Si layer is a Si layer selected from: single crystal Si, polycrystalline Si or amorphous Si.
The laser wavelength is between 150 nm and 900 nm, preferably between 250 nm and 550 nm.
The silicon Si layer is cleaned prior to depositing the cobalt Co layer.
The laser annealing step is performed while the plate is placed on a hot platen for maintaining the wafer at a temperature ranging from 25 to 500° C.
After the laser annealing step, the method includes rapid thermal annealing (RTA).
The thickness of the Co layer is equal to 3 nm, said Co layer being deposited onto a SOI substrate, the Si layer of which has a thickness of 33 nm and the buried insulating layer BOX has a thickness of 20 nm, the laser pulse duration being 160 ns and the energy density of the laser pulse being between 0.6 J/cm² and 0.775 J/cm².

The invention also relates to:
An electronic device such as a transistor, at least one zone of which, such as a drain and/or source and/or gate contact, is made of COSi₂ obtained by the method of the invention, or a Josephson type junction, part of which is made of COSi₂ obtained by the method according to one of the preceding claims.
a transistor whose drain and/or source and/or gate contacts are made of COSi₂ by the method of the invention.
a JoFET type transistor in which the drain and/or source are made of COSi₂ obtained by the method of the invention.

### BRIEF DESCRIPTION OF THE FIGURES

Further characteristics and advantages of the invention will be clearly apparent from the description thereof given hereinbelow, by way of indicating and in no way limited purposes, with reference to the appended figures, of which:

FIG. 1 represents, in the form of a flow chart, the different steps of the method of the invention,

FIG. 2, FIG. 3, FIG. 4, FIG. 5 and FIG. 10 represent the different steps of the method of FIG. 1,

FIG. 6 shows an image of a Si/CoSi₂/TiN stack obtained by the method of the state of the art and two images of two other Si/CoSi₂/TiN stacks obtained by the method according to the invention,

FIG. 7 represents the course of sheet resistance as a function of laser energy density for three different numbers of laser pulses,

FIG. 8 shows the simulated temperature course within a stack used in the method of the invention for several energy densities,

FIG. 9 shows the course of the critical superconductivity temperature as a function of the number of laser pulses, with and without additional RTA annealing.

For greater clarity, identical or similar elements are identified by identical reference signs throughout the figures.

### DETAILED DESCRIPTION OF THE INVENTION

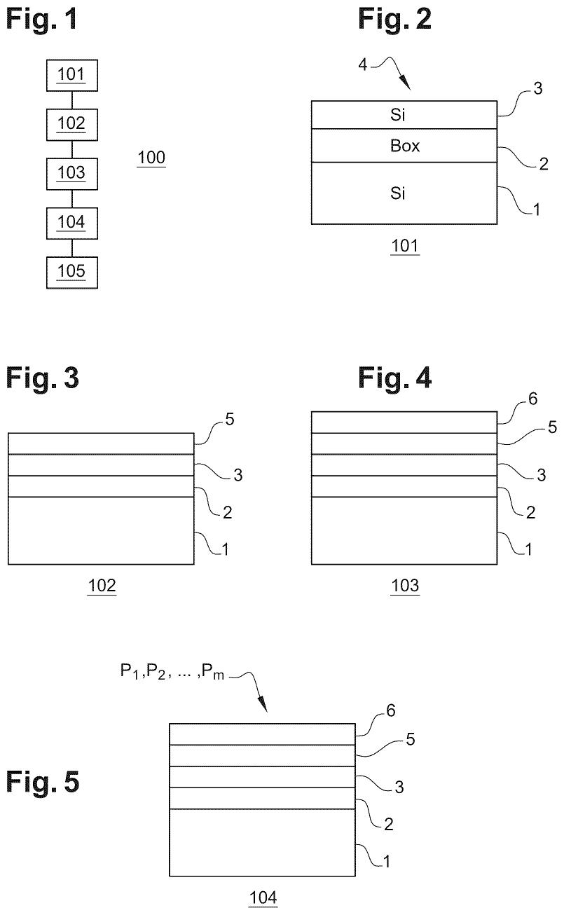

FIG. 1 represents the flow chart illustrating the different steps of the manufacturing method 100 according to the invention.

As shown in FIG. 2, the method 100 starts with an optional step 101 of cleaning 4 a silicon layer 3. The silicon layer 3 may, for example, be a single crystal silicon layer belonging to a substrate of the Silicon-On-Insulator (SOI) type including a lower silicon region 1 having thereabove a buried insulating layer 2 commonly designated by those skilled in the art as a “BOX”, for example formed of silicon dioxide. Above this buried insulating layer is situated the silicon layer 3. This cleaning aims at removing the chemical or native oxide initially present on the surface of the silicon layer 3. Cleaning can be carried out in one or two steps using one of the following techniques: wet process with a dilute HF hydrofluoric acid solution—abrasion by argon Ar plasma—SiCoNi® method. It will be noted that the method of the invention is not limited to a silicon layer present in an SOI substrate and can be applied to any type of Si layer, for example a fully single crystal Si substrate. Si onto which Co is deposited can be single crystal, polycrystalline or amorphous. Any stack is contemplatable under this Si layer. It would also be possible to make a CoSi₂ contact on another material, for example Ge, GeSn or SiGe, present under the silicon.

The method 100 according to the invention continues with a step 102 (FIG. 3) of depositing a cobalt layer 5 onto the silicon layer 3, immediately after the latter has been cleaned. This deposition is made, for example, by Physical Vapour Deposition (PVD). The thickness of the Co layer is between 0.5 and 50 nm and preferably between 0.5 nm and 10 nm and more preferably between 1 and 10 nm. Advantageously, the thickness of the Co layer is greater than or equal to 0.5 nm and strictly lower than 5 nm, and preferably greater than or equal to 0.5 nm and lower than or equal to 4 nm, and even more preferably greater than or equal to 1 nm and lower than or equal to 3.5 nm. According to this embodiment, the Co layer is directly deposited onto the Si layer. According to another embodiment, there could also be an oxide or nitride layer between the Si layer and the Co layer (in this case, the oxide or nitride layer preferably has a maximum thickness of 2 mm so that CoSi₂ can be formed).

In order to prevent oxidation of the Co layer 5 and the underlying Si layer 3, the method 100 according to the invention includes a step 103 (FIG. 4) of depositing an oxidation protective layer 6. This protective layer 6 may, for example, be made of TiN deposited by PVD. The material of the protective layer is selected not only to protect the Co and Si layers 5 and 3 from oxidation but also to absorb the laser radiation which will subsequently be used to heat the Co layer.

The method 100 according to the invention continues with a laser annealing step 104 (FIG. 5). This step 104 is made by means of a pulsed laser emitting at a frequency between 0.1 and 1000 Hz, preferably between 1 and 10 Hz and advantageously between 3 and 6 Hz, for example here 4 Hz (i.e. a pulse shot every 250 ms), one or more laser pulses Pi (i varying from 1 to n, with n a strictly positive integer) through the stack formed by the Si/Co/TiN layers. Each pulse Pi has a duration between 50 nanoseconds and 20 microseconds and preferably between 0.1 microsecond and 1 microsecond, for example 160 ns. The wavelength of the laser is between 150 nm and 900 nm and preferably between 250 nm and 550 nm; in other words, the laser, which is monochromatic by nature, has a beam with a wavelength preferably in the ultraviolet (for example, at 293, 308 or 355 nm) range but may also be selected in the blue or green (for example 532 nm) range, or even the red (for example 633 nm) range. This step 104 of laser annealing will make it possible to react Co with Si so as to obtain a CoSi₂ layer in the solid state during this step 104. It is essential to note that the energy density of the laser pulse or pulses applied is selected so that the Co, Si or any Co silicide (for example CoSi₂ materials never turn to the liquid state and remain in the solid state. It is understood that the laser used by the method of the invention operates in “step and repeat” mode, making it possible to shoot a single laser pulse or a train of controlled laser pulses onto a zone without any risk of overlap.

As will be seen later, it is possible to obtain the expected result with a single laser pulse, but also with a plurality of laser pulses, the pulse duration and energy density having to be selected to obtain CoSi₂ only in the solid state.

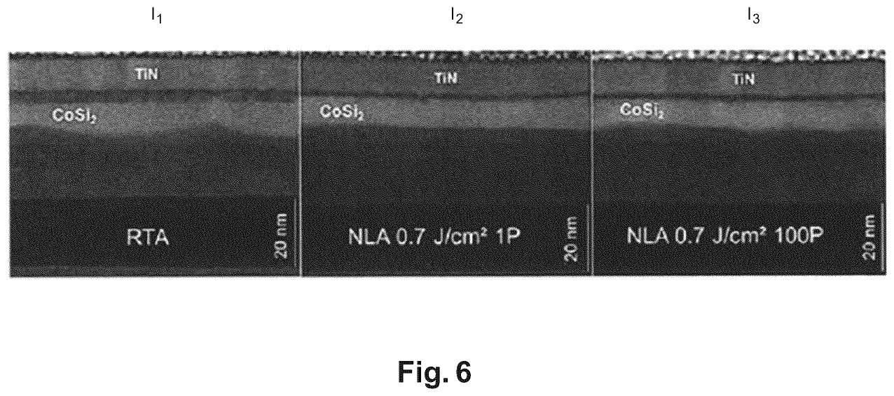

According to a first embodiment, during step 104 one or more laser pulses are applied at a constant energy density below the melting threshold of Co and all silicides CoSiₓ, especially CoSi₂. This first embodiment is illustrated for a sample made from a 3 nm thick Co layer deposited onto an SOI substrate (with a 20 nm BOX layer and a Si layer above 13 nm). A 10 nm TiN layer is deposited onto the Co layer. Each laser pulse used has a wavelength of 308 nm and a pulse duration of 160 ns. FIG. 6 illustrates the result obtained by the method of the invention compared with the method of prior art with two RTA steps: for this purpose, FIG. 6 shows an image 11 of a first Si/CoSi₂/TiN stack obtained by the method of prior art, an image 12 of a second Si/CoSi₂/TiN stack obtained by the method according to the invention using a single laser pulse at an energy density of 0.7 J/cm² and an image 13 of a third Si/CoSi₂/TiN stack obtained by the method of the invention using 100 identical pulses at an energy density of 0.7 J/cm². The Si/CoSi₂ interface of image 11 is less planar than the interfaces obtained by the method according to the invention (images 12 and 13). The planar Si/CoSi₂ interface according to the invention is especially advantageous for obtaining the Josephson effect in JoFET transistors.

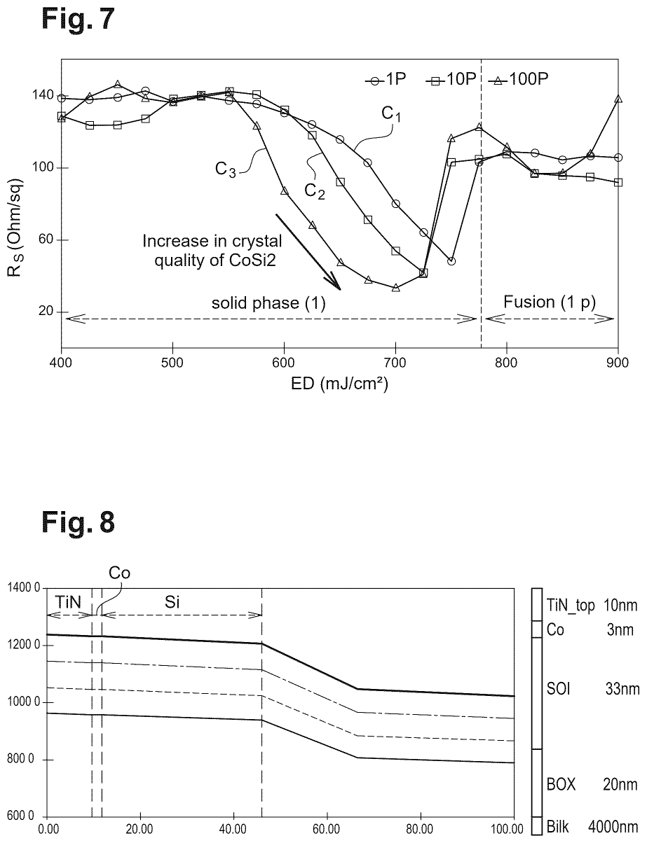

FIG. 7 shows the course of the sheet resistance Rsheet as a function of the energy density applied and the number of pulses applied to the previously described stack (Co layer with a thickness of 3 nm deposited onto a 33 nm SOI substrate and a 10 nm TiN layer deposited onto the Co layer). Curve C1 illustrates the course of Rsheet as a function of energy density when applying 1 pulse across the stack, curve C2 when applying 10 pulses across the stack and curve C3 when applying 100 pulses across the stack.

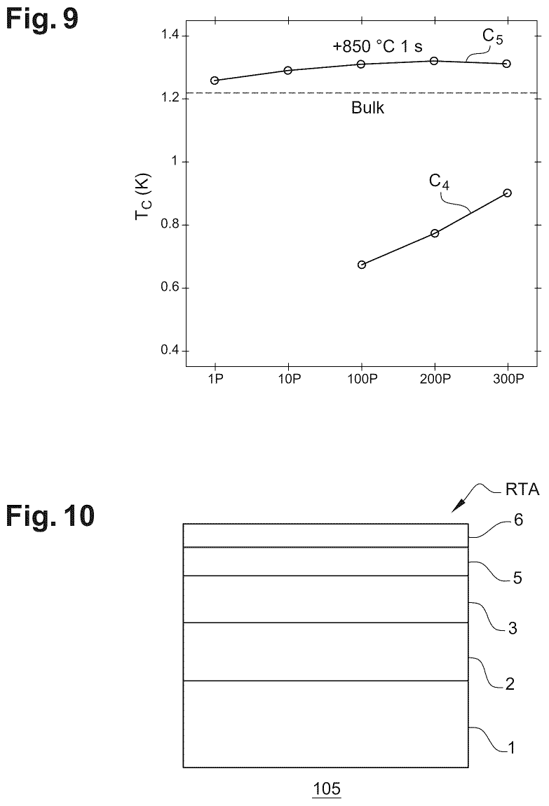

Each of these curves C1, C2 and C3 passes through a minimum corresponding to a CoS₂ phase having very good crystal quality (with a good interface with Si). As illustrated, when the number of pulses is increased, the energy density to reach the minimum of Rₛ decreases: indeed, an energy density in the order of 775 mJ/cm² is required to reach a minimum resistance Rs with a single pulse, whereas a density in the order of 725 mJ/cm² is used to reach a minimum resistance with 10 pulses and the minimum resistance Rs is reached at a density of 700 mJ/cm² for 100 pulses. This minimum resistance Rₛ additionally decreases with the number of pulses: thus, it is observed that the minimum sheet resistance for 100 pulses is lower than the minimum sheet resistance for 10 pulses, which is itself lower than the minimum sheet resistance for 1 pulse. Lower sheet resistance results in less resistive CoSi₂ contacts. Increasing the number of pulses at constant energy density additionally makes it possible to increase the critical superconductivity temperature Tc: this phenomenon is illustrated in FIG. 9, which shows on curve C4 the course of the critical temperature Tc as a function of the number of pulses: there is therefore a shift from a critical temperature in the order of 0.6K for 100 pulses to a critical temperature in the order of 0.9K for 300 pulses.

An alternative to increasing the number of pulses to reduce sheet resistance may be to increase the pulse duration. Insofar as the pulse shot frequency is about 4 Hz, it can be assumed that there will be no heat build-up between each shot and that the stack returns to room temperature between each shot. Thus, as a first approximation, a pulse lasting one microsecond is equivalent to ten pulses lasting 0.1 microsecond shot at 4 Hz.

Of course, it is suitable not to exceed a certain energy density coupled with the number of pulses and the pulse duration for the CoSi₂ not to turn to the liquid phase. Various experiments have shown that the solid phase of CoSi₂ is effectively formed for low Rs values (i.e. in the phase of decreasing Rs values observed on curves C1, C2 and C3) before reaching the liquid phase (i.e. melting of CoSi₂) during the phase of rising Rs values as the energy density increases. Profile results obtained by EDS-TEM spectroscopy (Energy Dispersive Spectroscopy—Transmission Electron Microscopy) have shown that the stoichiometry revealed in the samples obtained from laser annealing with 1 pulse, 10 pulses and 100 pulses is indeed that of CoSi₂. Furthermore, the laser annealing machine is equipped with another laser, referred to as secondary laser, tilted at 45° to the heating laser, for in-situ characterisation, enabling the course of the surface reflectivity during the laser pulse to be monitored. It has been noticed that a sharp increase in the reflectivity of the material occurs for a pulse from 775-800 mJ/cm², evidencing the transition to the liquid state. Additionally, this tool enables the laser strategy to be defined quickly without having to resort to more cumbersome characterisation techniques (such as TEM microscopy or X-ray diffractometry): it can especially be used to determine energy densities that must not be exceeded. In practice, the secondary laser sends a pulse before, during and after the annealing pulse sent by the primary laser: if a liquid phase is reached, a sudden change in reflectivity is observed. Finally, 1D simulations of the stack provided have been performed. FIG. 8 shows the temperature course within the stack for several energies. The maximum temperature recorded (in the order of 1220° C.) is below the melting temperature of all silicides CoSiₓ (in the order of 1350° C.). These simulations provide a non-destructive approach for anticipating energy densities to be applied to obtain CoSi₂ in the solid state.

According to a second embodiment, during step 104 several laser pulses are applied, at least the first of which has a different and higher energy density than the subsequent ones, while remaining below the melting threshold of Co and all the silicides CoSiₓ, especially CoSi₂. This second strategy therefore consists in adapting the energy density as silicidising progresses. Indeed, as mentioned above, it has been noticed that applying more pulses reduces the energy density required to form CoSi₂ while reducing the sheet resistance Rₛ. One solution may therefore be to apply a first pulse close to melting of CoSi₂, and then one or more pulses at a slightly lower density to reduce the sheet resistance Rₛ. The first pulse close to melting enables the cobalt to be partially transformed into CoSi₂ in the solid phase over a given thickness. The energy density of the laser pulses, especially the first one, can be determined beforehand by tests made on samples using the secondary laser in order to achieve an energy density close to melting without reaching the liquid phase. From this new stack, one or more further laser pulses are made until the desired sheet resistance Rs is reached, by reducing the total number of pulses relative to the first embodiment (constant energy density) to achieve the same sheet resistance value Rs.

It will be noted that it is optionally possible, prior to the laser annealing step 104, to place the stack obtained at the end of step 103 on a hot platen at a predetermined temperature, for example 400° C., to wait for the stack to reach the predetermined temperature, and then to apply the laser pulse or pulses while the stack is on the hot platen at the predetermined temperature. The use of such a plate makes it possible, in particular, to lengthen the annealing time at the desired temperature.

The method 100 according to the invention can additionally include a step 105 illustrated in FIG. 10 consisting in applying a rapid thermal annealing of the RTA type as an extension of the pulsed laser annealing. This rapid RTA annealing is made, for example, by conduction using heating blocks in proximity to the stack, it being understood that other types of RTA could be implemented (microwave or UV source, for example). The addition of this RTA step makes it possible to significantly improve the critical superconductivity temperature Tc. As illustrated in FIG. 9 showing the course C5 of the critical temperature Tc as a function of the number of pulses in the presence of RTA annealing at 850° C. for 1 sec, it is possible to reach a superconductivity critical temperature of 1.3° K, i.e. a gain ranging from 44% to 100% relative to critical temperatures of 0.6 to 0.9° K of the curve C4 without RTA.

It will be noted that obtaining satisfactory superconductivity for the cobalt silicide obtained by the method of the invention is greatly improved by starting with single crystal silicon and a thin cobalt layer (i.e. lower than or equal to 10 nm, or even strictly lower than 5 nm) as well as by virtue of the finishing RTA step (i.e. after the laser annealing step).

Of course, once the CoSi₂ layer has been made, the method of the invention can be continued with removing the TiN oxidation protective layer.

1. A method for manufacturing a cobalt silicide CoSi₂ layer, the method comprising:
providing a substrate comprising a single crystal silicon layer;
depositing a cobalt Co layer onto the substrate, the thickness of the Co layer being between 0.5 nm and 10 nm;
annealing the stack by a nanosecond laser comprising at least one laser pulse with a duration between 50 nanoseconds and 20 microseconds and an energy density selected so as to form the layer of cobalt silicide CoSi₂ in the solid state,
after the annealing the stack by the nanosecond laser, rapid thermal annealing RTA the stack.

2. The method according to claim 1, further comprising depositing a layer protecting Co and/or Si against oxidation onto the Co layer before the annealing.

3. The method according to claim 1,
wherein laser annealing is performed by a nanosecond laser operating in step and repeat mode.

4. The method according to claim 1, wherein the duration of the laser pulse is between 0.1 microsecond and 1 microsecond.

5. The method according to claim 1, wherein the laser annealing is performed in the form of a single laser pulse.

6. The method according to claim 1, wherein laser annealing is performed in the form of a plurality of laser pulses.

7. The method according to claim 5, wherein each laser pulse of said plurality of laser pulses is emitted with a same energy density.

8. The method according to claim 5, wherein the first laser pulse of said plurality of laser pulses has a higher energy density than the subsequent pulses, the energy density of the first pulse being selected close to but strictly lower than the energy density causing melting of cobalt silicide CoSi₂.

9. The method according to claim 1, wherein a thickness of the Co layer is greater than or equal to 0.5 nm and strictly lower than 5 nm.

10. The method according to claim 1, wherein the wavelength of the laser is between 150 nm and 900 nm.

11. The method according to claim 1, wherein the silicon Si layer is cleaned, prior to the deposition of the cobalt Co layer.

12. The method according to claim 1, wherein the laser annealing performed on a hot platen for maintaining the plate at a temperature ranging from 25 to 500° C.

13. The method according to claim 1, wherein the thickness of the Co layer is equal to 3 nm, said Co layer being deposited onto an SOI substrate the Si layer of which has a thickness of 33 nm and the buried insulating layer BOX has a thickness of 20 nm, the laser pulse duration being 160 ns and the energy density of the laser pulse being between 0.6 J/cm² and 0.775 J/cm².

14. An electronic device, comprising at least one zone made of CoSi₂ obtained by the method according to claim 1.

15. The method according to claim 2, wherein the layer protecting Co and/or Si against oxidation is a TiN layer.

16. The method according to claim 9, wherein the thickness of the Co layer is greater than or equal to 0.5 nm and lower than or equal to 4 nm.

17. The method according to claim 16, wherein the thickness of the Co layer is greater than or equal to 1 nm and lower than or equal to 3.5 nm.

18. The method according to claim 1, wherein the wavelength of the laser is between 250 nm and 550 nm.

19. The electronic device according to claim 14, wherein the electronic device is a transistor.

20. The electronic device according to claim 14, wherein the at least one zone is a drain, a source or a gate contact.
